(19) United States
(12) Patent Application Publication
(10) Pub. No.: US 2023/0299751 A1
(43) Pub. Date: Sep. 21, 2023

(54) INTERPOLATION FILTER DEVICE, SYSTEM AND METHOD

(71) Applicant: STMicroelectronics International N.V., Geneva (CH)

(72) Inventors: Ankur BAL, Greater Noida (IN); Gaurav AGGARWAL, Delhi (IN)

(73) Assignee: STMicroelectronics International N.V., Geneva (CH)

(21) Appl. No.: 18/185,130

(22) Filed: Mar. 16, 2023

Related U.S. Application Data
(60) Provisional application No. 63/321,954, filed on Mar. 21, 2022.

(51) Int. Cl. H03H 17/06; H03H 17/02

(52) U.S. Cl. CPC H03H 17/0657; H03H 17/0275

(57) ABSTRACT

A method generates a delayed signal based on an input signal, and applies vector magnitude scaling to the delayed signal, generating one or more vector magnitude scaled signals. The input signal is added to the one or more vector magnitude scaled signals, generating one or more phase-shifted signals. Compensation scaling is applied to the one or more phase-shifted signals, generating one or more compensated signals. The input signal and the one or more compensated signals are combined, generating an interpolated output signal. The method may be implemented by a device or a system.

### BACKGROUND

### Technical Field

The disclosure generally relates to the field of digital filters for interpolation or decimation.

### Description of the Related Art

Digital filters or multi-rate digital filters are used in digital communication, telecommunications, speech processing, image compression, antenna/radar systems, spectrum analysis, control systems such as traction control systems, etc.

Interpolation filters or interpolators increase the sampling rate of an input digital signal, and are usually implemented using polyphase filter banks. On the other hand, decimations filters or decimators decrease the sampling rate of an input digital signal.

Multi-rate change in data-conversion for achieving different throughputs while maintaining performance is a challenge. For example, polyphase interpolation filters are bulky and complex to design for programmable interpolation factors. Area, power overhead may be high for polyphase interpolation filters.

### BRIEF SUMMARY

In an embodiment, a device includes an input, which, in operation, receives an input signal, a phase delay element coupled to the input, which, in operation, generates a delayed signal based on the input signal, vector magnitude scaling circuitry coupled to the phase delay element, which, in operation, applies vector magnitude scaling to the delayed signal, generating one or more vector magnitude scaled signals. Adding circuitry coupled to the input and to the vector magnitude scaling circuitry, in operation, adds the input signal to the one or more vector magnitude scaled signals, generating one or more phase-shifted signals. Magnitude compensation scaling circuitry coupled to the adding circuitry applies compensation scaling to the one or more phase-shifted signals, generating one or more compensated signals. The device includes multiplexing circuitry coupled to the input and to the magnitude compensation circuitry, which, in operation, combines the input signal and the one or more compensated signals, generating an interpolated output signal.

In an embodiment, a method generates a delayed signal based on an input signal, and applies vector magnitude scaling to the delayed signal, generating one or more vector magnitude scaled signals. The input signal is added to the one or more vector magnitude scaled signals, generating one or more phase-shifted signals. Compensation scaling is applied to the one or more phase-shifted signals, generating one or more compensated signals. The input signal and the one or more compensated signals are combined, generating an interpolated output signal.

In an embodiment, a system includes a memory and interpolation circuitry coupled to the memory. The interpolation circuitry includes an input, which, in operation, receives an input signal, and a phase delay element coupled to the input, the phase delay element, in operation, generates a delayed signal based on the input signal. Vector magnitude scaling circuitry coupled to the phase delay element, in operation, applies vector magnitude scaling to the delayed signal, generating one or more vector magnitude scaled signals. Adding circuitry coupled to the input and to the vector magnitude scaling circuitry, in operation, adds the input signal to the one or more vector magnitude scaled signals, generating one or more phase-shifted signals. Magnitude compensation scaling circuitry coupled to the adding circuitry, in operation, applies compensation scaling to the one or more phase-shifted signals, generating one or more compensated signals. Multiplexing circuitry coupled to the input and to the magnitude compensation circuitry, in operation, combines the input signal and the one or more compensated signals, generating an interpolated output signal.

In an embodiment, a non-transitory computer readable medium's contents cause interpolation circuitry to perform a method. The method includes generating a delayed signal based on an input signal, applying vector magnitude scaling to the delayed signal, generating one or more vector magnitude scaled signals, adding the input signal to the one or more vector magnitude scaled signals, generating one or more phase-shifted signals, applying compensation scaling to the one or more phase-shifted signals, generating one or more compensated signals, and combining the input signal and the one or more compensated signals, generating an interpolated output signal.

### BRIEF DESCRIPTION OF THE SEVERAL VIEWS OF THE DRAWINGS

Non-limiting and non-exhaustive embodiments are described with reference to the following drawings, wherein like labels refer to like parts throughout the various views unless the context indicates otherwise. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings. Moreover, some elements known to those of skill in the art have not been illustrated in the drawings for ease of illustration. One or more embodiments are described hereinafter with reference to the accompanying drawings in which:

FIG. 1 is a functional block diagram of an example interpolation architecture according to some embodiments of the present disclosure.

FIGS. 2A to 2C are conceptual diagrams illustrating an embodiment of a method of generating a phase-shifted signal.

FIGS. 3A and 3B illustrate example interpolation architectures according to some embodiments of interpolation by 2.

FIG. 4 illustrates an embodiment of a method of interpolation.

FIGS. 5A and 5B are conceptual diagrams illustrating a method of fractional interpolation according to some embodiments of the present disclosure.

FIGS. 6A and 6B illustrate example interpolation architectures according to some embodiments.

FIG. 7 is an example system block diagram according to some embodiments of the present disclosure.

FIG. 8 illustrates an example embodiment of a system employing an interpolation architecture according to some embodiments of the present disclosure.

FIG. 9 illustrates an example embodiment of a system that incorporates an interpolation architecture according to some embodiments of the present disclosure.

### DETAILED DESCRIPTION

The following description, along with the accompanying drawings, sets forth certain specific details in order to provide a thorough understanding of various disclosed embodiments. However, one skilled in the relevant art will recognize that the disclosed embodiments may be practiced in various combinations, without one or more of these specific details, or with other methods, components, devices, materials, etc. In other instances, well-known structures or components that are associated with the environment of the present disclosure, including but not limited to interfaces, power supplies, physical component layout, etc., have not been shown or described in order to avoid unnecessarily obscuring descriptions of the embodiments. Additionally, the various embodiments may be methods, systems, or devices.

Throughout the specification, claims, and drawings, the following terms take the following meanings, unless the context indicates otherwise. The term “herein” refers to the specification, claims, and drawings associated with the current application. The phrases “in one embodiment,” “in another embodiment,” “in various embodiments,” “in some embodiments,” “in other embodiments,” and other variations thereof refer to one or more features, structures, functions, limitations, or characteristics of the present disclosure, and are not limited to the same or different embodiments unless the context indicates otherwise. As used herein, the term “or” is an inclusive “or” operator, and is equivalent to the phrases “A or B, or both” or “A or B or C, or any combination thereof,” and lists with additional elements are similarly treated. The term “based on” is not exclusive and allows for being based on additional features, functions, aspects, or limitations not described, unless the context indicates otherwise. In addition, throughout the specification, the meaning of “a,” “an,” and “the” include singular and plural references.

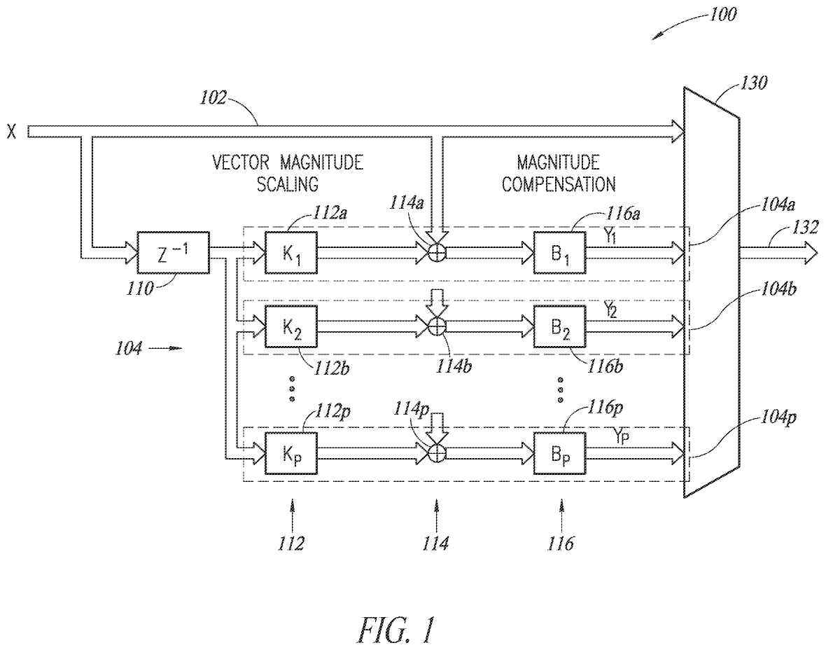

FIG. 1 is a functional block diagram of an example interpolation architecture 100 according to some embodiments of the present disclosure. The interpolation architecture or circuit 100 includes an input line 102, a phase delay element 110, a plurality of interpolation branches 104, as illustrated, interpolation branches 104a to 104p, and multiplexing circuitry 130. The number of interpolation branches 104 employed during a particular interpolation process depends on a number of samples N to be included in an interpolated output signal 132 generated by the multiplexer 130 in a period or cycle of the output signal. For example, in the case of interpolation by 2, there will be one branch in addition to the input line 102, (in this case, p is 1), and the interpolated output will combine (e.g., time multiplex) the input signal and the output of the branch. In the case of interpolation by 10, there will be the input line and nine branches (in this case, p is 9), and the interpolated output will combine (e.g., time multiplex) the input signal and the nine outputs of the nine branches. In the case of fractional interpolation, (e.g., the ratio of the output rate to the input rate is fractional), the number of branches to be employed may be selected to facilitate providing at output corresponding to the desired fractional interpolation period.

The input line 102 receives an input signal X, which may be conceptually represented as:

$$X = {\sum }_{K < N} sin ( 2 * π * k * \frac{n}{2 N} ) ,$$

where, n represents a time stamp, N represents a number of samples, and k/N represents a digital sampling frequency.

The phase delay element 110 represented by z⁻¹ (also referred to as a phase delay circuit 110) is coupled between the input line 102 and the one or more interpolation branches 104a to 104p, and generates a delayed version X(n−1) of the input signal X (which may be referred to as a delayed signal).

The interpolation branches 104 of the interpolation architecture 100 as illustrated include vector magnitude scaling circuitry 112, including vector magnitude scaling branches 112a to 112p as illustrated, adding circuitry 114, including adding branches 114a to 114p as illustrated, and magnitude compensation scaling circuitry 116, including magnitude compensation branches 116a to 116p as illustrated.

The vector magnitude scaling circuitry 112 performs vector magnitude scaling on the phase delayed signal X(n−1). For example, each branch 112a to 112p of the vector magnitude scaling circuitry 112 applies a respective vector magnitude scaling factor Kᵢ (where i=1 to p as illustrated), to the phase delayed signal X(n−1), generating a vector magnitude scaled signal for the branch 104i that may be represented as KᵢX(n−1).

For example, in an embodiment Kᵢ may be determined according to:

$${Tan}^{- 1} ( \frac{{K}_{i} sin ( β )}{1 + {K}_{i} cos ( β )} ) = \frac{i β}{N} ,$$

where β represents the digital angular frequency.

The adding circuitry 114 is coupled to the input line 102 and to the vector magnitude scaling circuitry 112. For example, each branch 114i (where i=1 to p as illustrated) of the adding circuitry 114 adds the input signal X received on the input line 102 to a vector magnitude scaled signal KᵢX(n−1) generated by the corresponding vector magnitude scaling branch 112i, generating a phase-shifted signal for the branch 104i of the interpolation circuitry 104, which may be represented as X(n)+K₁X(n−1).

A sinusoid can be expressed as a linear combination of a sine and a cosine. Conversely, a linear combination of two or more sinusoids can be expressed as a linear combination of a sine and a cosine, hence can be expressed as a single sinusoid. It can be shown that the vector summation of two sinusoidal functions f(t) and g(t) with the same frequency ω but with phase difference φ and amplitudes A and B respectively will result in another sine wave h(t) with the same frequency co but different amplitude C and phase ψ. This may be represented as:

f(t)=A sin(ωt)

g(t)=B sin(ωt+φ)

h(t)=C sin(ωt+ψ)

C=B sin(φ)/sin(ψ)

ψ=tan⁻¹(B sin(φ)/(A+B cos(φ)))

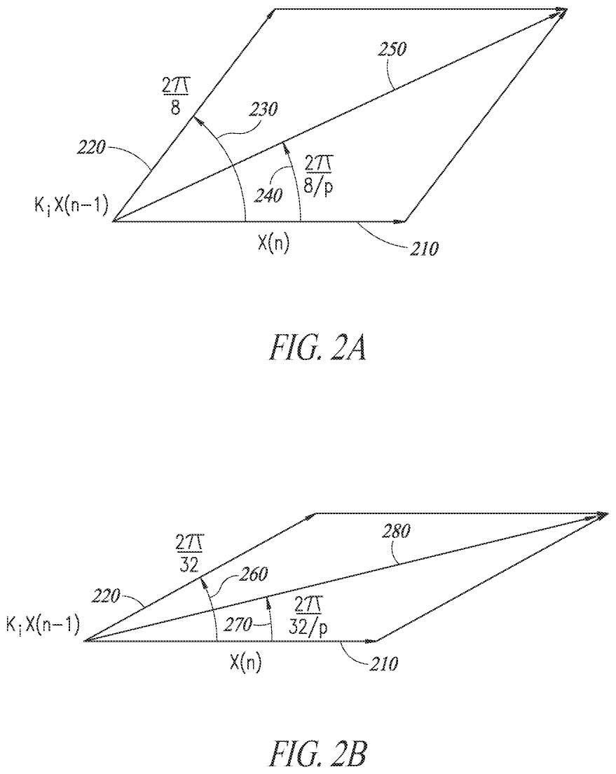

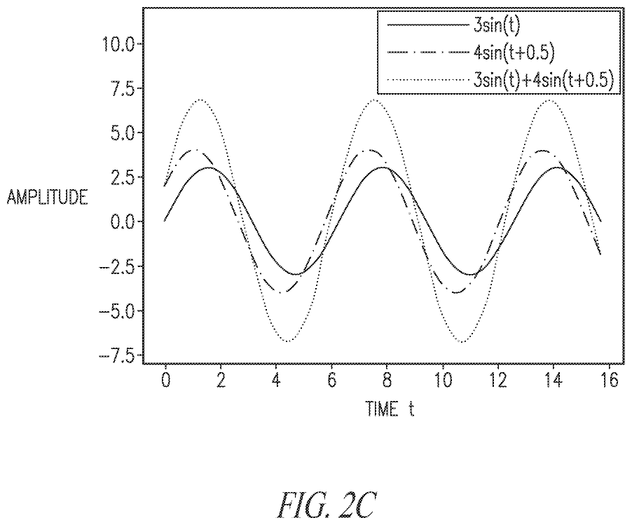

FIGS. 2A and 2B are conceptual diagrams illustrating the addition of an input signal X(n) (represented as a vector 210) and a vector magnitude scaled signal KᵢX(n−1) (represented as a vector 220) of a branch 104i. In FIG. 2A, the phase difference between vector 210 and vector 220 is indicated as phase difference 230. Adding the vectors 210, 220 results in phase-shifted vector 250, which has a different phase difference 240 with respect to the input vector 210, which is less than the phase difference 230, and a different magnitude (illustrated as a length of the vector 250) than a magnitude of vector 210. FIG. 2B shows a similar example that results in a vector 280 that has a different phase difference 270 with the vector 210 and a different magnitude than the magnitudes of the vectors 210 and 250.

FIG. 2C is a conceptual diagram illustrating an example of the generation of a phase-shifted signal X(n)+K₁X(n−1). The input signal X(n) is represented as X=3 sin(t) in FIG. 2C. The vector magnitude scaled signal KᵢX(n−1), represented as 4 sin(t+0.5) in FIG. 2C, has been scaled 4/3 from input signal X(n) with a phase shift of +0.5. The phase-shifted signal X(n)+K₁X(n−1) generated by adding the input signal X(n) and the vector magnitude scaled signal KᵢX(N−1) is represented as 3 sin(t)+4 sin(t+0.5) in FIG. 2C.

As shown in FIGS. 2A, 2B, and 2C, the magnitudes of the phase-shifted signals X(n)+K₁X(n−1) generated by the adding circuitry 114 (e.g., 114a to 114p) are different from the magnitude of the input signal X(n). Referring back to FIG. 1, magnitude compensation scaling circuitry 116 performs magnitude compensation scaling on the phase-shifted signals X(n)+KᵢX(n−1) so the signals of the input and of the interpolation branches are usable when combined (e.g., to normalize the phase-shifted signals X(n)+KᵢX(n−1)), generating one or more compensated signals. For example, each branch 116a to 116p of the magnitude compensation scaling circuitry 116 applies a respective magnitude scaling factor Bᵢ (where i=1 to p as illustrated), to the phase-shifted signal X(n)+KᵢX(n−1), generating a compensated signal Yᵢ for the branch 104i that may be represented as Bᵢ(X(n)+KᵢX(n−1)).

For example, in an embodiment, the scaling factor Bᵢ may be determined according to:

$${B}_{i} = \frac{1}{\sqrt{1 + {K}_{i}^{2} + 2 {K}_{i} cos ( β )}} .$$

Scaling factor Bᵢ is a filter/gain of the magnitude compensation scaling circuitry 116 that seeks to flatten the magnitude of frequency response so that the interpolated outputs are not scaled relative to the input and each other by the vector magnitude scaling circuitry 112 and the adding circuitry 114. The output from the adding circuitry 114 is an interpolated signal, but its magnitude (or amplitude) is different for different input frequencies. The magnitude compensation scaling circuitry 116 applies an inverse magnitude transfer function to compensate for the magnitude differences introduced by the phase-shifting.

The multiplexing circuitry 130 is coupled to the input line 102 and to the magnitude compensation scaling circuitry 116. The multiplexing circuitry 130, in operation, combines the input signal and the one or more compensated signals (e.g., Y₁, Y₂, . . . Yₚ) to generate an interpolated output signal 132. The multiplexing circuitry may be configured, for example, to generate an interpolated output signal 132 by time multiplexing the signal on the input line 102 and one or more of the compensated signals Yᵢ generated by the magnitude compensation scaling circuitry, to select one or more of the input signal 102 and the one or more of the compensated signals Yᵢ to provide at a particular time instant, etc. The multiplexing circuitry 130 may have one or more control signal inputs, a state machine, etc., to control how the signals received by the multiplexing circuitry 130 are combined to generate the output signal 132.

In an embodiment, the interpolation circuitry 104 may have a fixed number of branches 104i, and the number of branches to employ to perform a particular interpolation operation being based on the number of samples N to be provided in the output 132. If N is fixed in a particular application (e.g., the interpolation to be applied is always interpolation by 3), the number of branches may be fixed accordingly (e.g., two branches when the interpolation is fixed at 3).

As noted above, the output Yᵢ of a branch 104i may be represented as:

Yᵢ=Bᵢ·(X(n)+KᵢX(n−1)).

Yᵢ may be determined according to input signal X(n) as follows:

$${Y}_{i} = {B}_{i} \cdot ( X ( n ) + {K}_{i} X ( n - 1 ) ) = {B}_{i} \cdot ( cos ( β n ) + {K}_{i} cos ( β n + β ) )$$

$$where$$

$$β = \frac{2 π f}{{f}_{s}}$$

Here, β represents the angular frequency (β=2πf_{d}), where f_{d} is the digital frequency and is defined as f_{d}=fᵢ/fₛ, where fᵢ represents the analog signal frequency and fₛ represents the sampling frequency.

Yᵢ also may be represented as follows:

$${Y}_{i} = {B}_{i} \cdot ( \sqrt{1 + {K}_{i}^{2} + 2 {K}_{i} cos ( β )} cos ( β n + {tan}^{- 1} ( \frac{{K}_{i} sin ( β )}{1 + {K}_{i} cos ( β )} ) )$$

The output signal magnitude is represented as Bᵢ·(\sqrt{1+Kᵢ²+2Kᵢ cos(β)} and its phase is represented as tan⁻¹

$$( \frac{{K}_{i} sin ( β )}{1 + {K}_{i} cos ( β )} )$$

The signal X(n) and the signals Yᵢ may be time multiplexed by the multiplexer circuitry 130 to produce the interpolated output signal 132, which may be represented as ((X(n), Yₐ, Y_{b}, . . . Yₚ)). The example interpolation architecture 100 of FIG. 1 may be implemented as a multi-mode interpolator, such as an embodiment of a multi-mode interpolator shown in FIG. 9.

With respect to computing the scaling elements, such as the vector magnitude scaling factor Kᵢ and the magnitude compensation scaling factor Bᵢ, examples will be provided below for interpolation by 2 and interpolation by 3. A person of ordinary skill in the art would readily understand how to compute the scaling elements based on the example formula provided. The specific formula for deriving each scaling elements may differ for each filter design.

As noted above, Kᵢ can be determined based on the following relationship:

$${tan}^{- 1} ( \frac{{K}_{i} sin ( β )}{1 + {K}_{i} cos ( β )} ) = \frac{i β}{N}$$

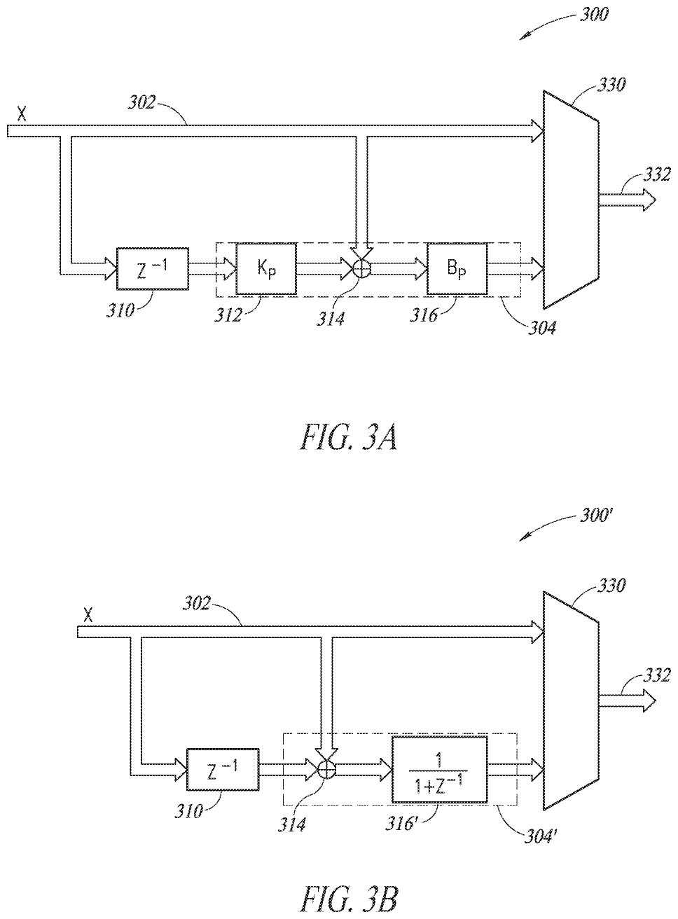

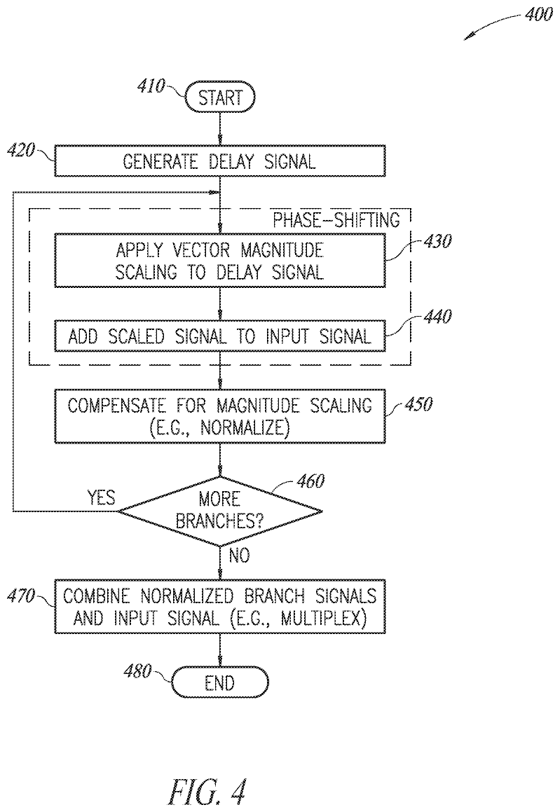

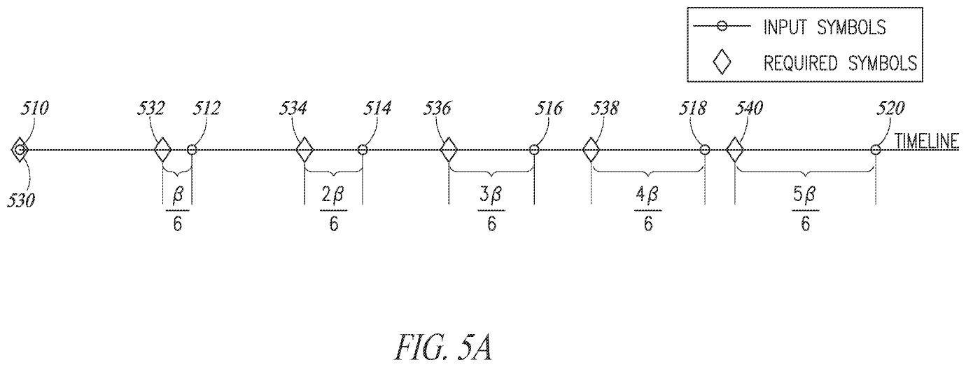

FIG. 3A illustrates an example that is interpolated by 2 (p=1 and N=2). The example of FIG. 3A illustrates a system 300 including an input line 302 supplying an input signal X (which may be represented as X=cos(βn)), a phase delay element 310, a first branch 304 having vector magnitude scaling circuitry 312, adding circuitry 314, and magnitude compensation scaling circuitry 316, and multiplexer circuitry 330. The multiplexer circuitry 330 produces an output signal 332 based on the input signal on line 302 and a compensated signal output by the magnitude compensation scaling circuitry 316 of the branch 304. FIG. 3A may be viewed as an embodiment of FIG. 1 where N is 2 and p is 1. In other words, FIG. 3A represents an embodiment providing interpolation by 2.

Based on the representation of Yᵢ set forth above, the vector magnitude scaling factor K₁ in an example case of interpolation by 2 may be determined according to:

$${tan}^{- 1} ( \frac{{K}_{i} sin ( β )}{1 + {K}_{i} cos ( β )} ) = \frac{β}{2}$$

$${K}_{1} = \frac{tan ( \frac{β}{2} )}{sinβ - cosβ * tan ( \frac{β}{2} )} = 1$$

The gain of the compensated signal generated by the magnitude compensation scaling circuitry 316 may be represented as:

B₁·(\sqrt{1+K₁²+2K₁ cos(⊕)})=1.

Solving for B₁ when K₁ is 1 leads to:

$${B}_{1} = \frac{1}{\sqrt{2 + 2 cos ( β )}} = \frac{1}{2 cos ( \frac{β}{2} )} = \frac{1}{1 + {z}^{- 1}}$$

Thus, the interpolation by 2 of system 300 of FIG. 3A may alternatively be implemented using a simplified architecture 300′ as shown in FIG. 3B. In FIG. 3B, the vector magnitude scaling circuitry 312 of FIG. 3A may be omitted because Kₚ is 1. Thus, the interpolation circuitry 304′ of FIG. 3B need not include vector magnitude scaling circuitry, and the adder 314, in operation, adds the output of the phase delay element 310 to the input signal X on input line 302. The magnitude compensation scaling circuitry 316′ of FIG. 3B may be implemented using a low pass filter.

It is noted that for an interpolate by 2 system, vector magnitude scaling is not required. This can shown to be is true for interpolation factors in powers of 2. A cascading low-pass filter architecture may be employed to implement interpolation factors in powers of 2.

Similarly, when interpolated by 3 (p=2 and N=3), Kᵢ may be determined according to:

$${tan}^{- 1} ( \frac{{K}_{p} sin ( β )}{1 + {K}_{p} cos ( β )} ) = \frac{p β}{N}$$

When p=1 and N=3, K₁ is determined as:

$${K}_{1} = \frac{tan ( - \frac{β}{3} )}{sin ( β ) - cos ( β ) * tan ( - \frac{β}{3} )} = \frac{{z}^{- \frac{1}{3}}}{1 + {z}^{- \frac{2}{3}}}$$

When p=2 and N=3, K₂ is determined as:

$${K}_{1} = \frac{tan ( - \frac{2 * β}{3} )}{sin ( β ) - cos ( β ) * tan ( - 2 * \frac{β}{3} )} = {z}^{\frac{1}{3}} ( 1 + {z}^{- \frac{2}{3}} )$$

Bᵢ may be determined according to:

$${B}_{i} = \frac{1}{\sqrt{1 + {K}_{i}^{2} + 2 {K}_{i} cos ( β )}}$$

Based on the K₁ and K₂ values above, B₁ and B₂ may be determined as follows.

$${B}_{1} = \frac{sin ( \frac{β}{3} )}{sin ( β )} = \frac{{z}^{- 2}}{1 + {z}^{- 2} + {z}^{- 4}}$$

$${B}_{2} = \frac{sin ( \frac{2 β}{3} )}{sin ( β )} = \frac{{z}^{- 1} ( 1 + {z}^{- 2} )}{1 + {z}^{- 2} + {z}^{- 4}}$$

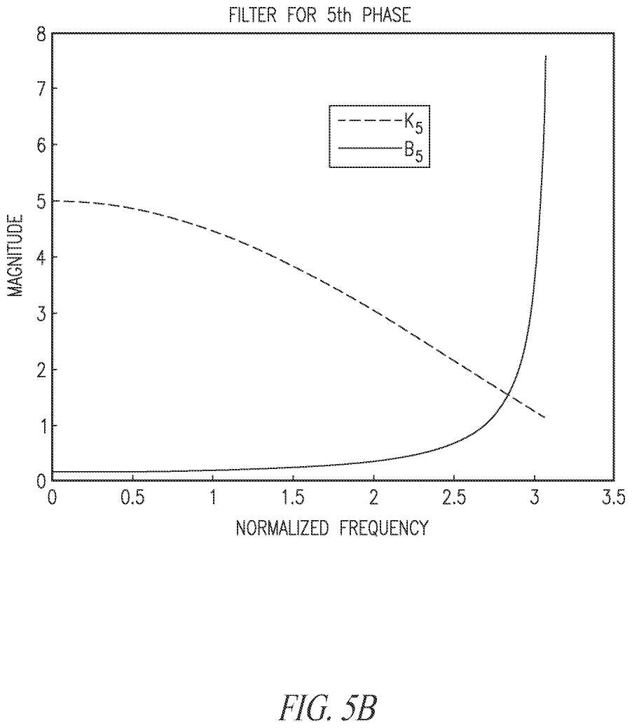

Other interpolation factors may be employed in various embodiments, including fractional interpolations (see, e.g., FIG. 5 discussed below).

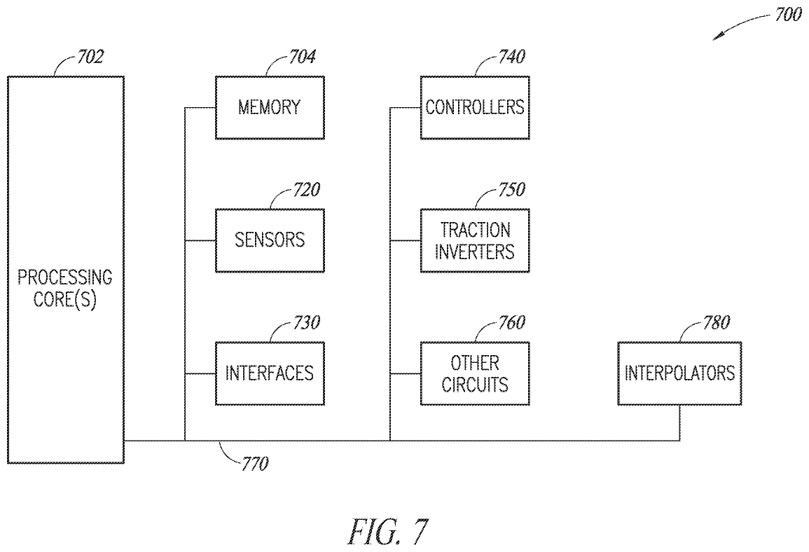

FIG. 4 illustrates an embodiment of a method 400 of interpolation that may be performed, for example, by the embodiment of an interpolation architecture 100 of FIG. 1, by the embodiments of FIGS. 3A and 3B, by the embodiment of a system 700 of FIG. 7, etc., and will be described for convenience with reference to the interpolation architecture 100 of FIG. 1 and the system 700 of FIG. 7.

The process 400 begins at 410, where an input signal X (or X(n)) to be interpolated is received. With reference to the interpolation architecture of FIG. 1, the input signal X(n) is received on the input line 102.

Process 400 proceeds from 410 to 420, where the input signal X is delayed, for example using phase delay circuit 110 of FIG. 1, generating a phase delayed signal. The resulting delay signal may be represented as X(n−1) as previously described.

Process 400 proceeds from 420 to 430, where vector magnitude scaling is applied to the phase delayed signal, generating a vector magnitude scaled signal. With reference to FIG. 1, the delayed signal X(n−1) from the phase delay circuit 110 is provided to a vector magnitude scaling circuitry 112, which applies a vector magnitude scaling factor Kᵢ, generating a vector magnitude scaled signal. The vector magnitude scaled signal may be represented as KᵢX(n−1). Applying vector magnitude scaling may include determining a vector magnitude scaling factor Kᵢ to apply, for example, using the equations described above. A look-up table may be employed to determine a vector magnitude scaling factor Kᵢ to apply by vector magnitude scaling circuitry 112ᵢ, for example, based on an interpolation number. In some embodiments, Kᵢ may be a fixed set of respective values to be applied by vector magnitude scaling circuits 112ᵢ.

Process 400 proceeds from 430 to 440, where the vector magnitude scaled signal KᵢX(n−1) is added to the input signal X(n−1), generating a phase-shifted signal. With reference to FIG. 1, the vector magnitude scaled signal KᵢX(n−1) is added to the input signal X(n) by adding circuitry 114, generating a phase-shifted signal. The phase-shifted signal may be represented as X(n)+KᵢX(n−1). FIGS. 2A and 2B illustrate examples of adding signals to obtain phase-shifted signals. As illustrated in FIG. 4, acts 430 and 440 together perform a phase-shifting process.

Process 400 proceeds from 440 to 450, where the magnitude scaling compensation is performed on the phase-shifted signal, generating a compensated signal. For example, the phase-shifted signal may be normalized with respect to the input signal. With reference to FIG. 1, the magnitude compensation scaling circuitry 116 applies magnitude compensation scaling factor Bᵢ to the phase-shifted signal, generating a compensation signal. The compensated signal may be represented as Bᵢ(X(n)+KᵢX(n−1)). Applying magnitude compensation scaling may include determining a magnitude compensation scaling factor Bᵢ to apply, for example, using the equations described above. A look-up table may be employed to determine the magnitude compensation scaling factor Bᵢ to apply by magnitude compensation scaling circuitry 116ᵢ, for example, based on an interpolation number. In some embodiments, Bᵢ may be a fixed set of respective values to be applied by magnitude compensation scaling circuits 116ᵢ.

Process 400 proceeds from 450 to 460, where it is determined whether additional compensated signals are needed to generate an interpolated signal according to the interpolation number N. When it is determined that more compensated signals are needed, the process 400 returns from 460 to 430 to generate another compensated signal in acts 430 to 450. In an embodiment, a control variable i may be incremented. When it is not determined that additional compensated signals are needed to generate the interpolated signal, the process proceeds from 460 to 470.

At 470, the compensated (or normalized) signals and the input signal are combined. With reference to FIG. 1, the multiplexer circuitry 130 receives the input from the input line 102, and the compensated signals from the branches 104i, and combines the signals to generate an interpolated signal. For example, time multiplexing may be employed. In another example, a selected one of the signals provided to the multiplexer circuitry may be provided at the output at a desired time. The process 400 proceeds from 470 to 480, where the process may terminate or perform other functions, such as returning to 410 to process a next sample of the input signal.

Embodiments of the foregoing processes and methods may contain additional acts not shown in FIG. 4, may not contain all of the acts shown in FIG. 4, may perform acts shown in FIG. 4 in various orders, may combine acts, and may be modified in various respects. For example, instead of using a loop and generating a set of compensated signals in series, then combining the set of compensated signals, parallel processing may be employed to generate and output a plurality of compensated signals in parallel.

FIG. 5A is a conceptual diagram illustrating a method of fractional interpolation according to some embodiments of the present disclosure. In particular, FIG. 5A illustrates a fractional interpolation with an interpolation number of 6 divided by 5 (N=6/5=1.2).

Conventionally, fractional interpolation involves up-sampling a signal (e.g., inserting 5 zeroes), applying a low pass filter, and down-sampling (e.g., decimation by 6). This approach requires at least two steps.

Referring back to FIG. 5A, input signals 510, 512, 514, 516, 518, and 520 are evenly spaced apart 1 unit of time in the timeline. The desired output signals are 530, which coincides with the input sample at 510, 532, 534, 536, 538 and 540, which are spaced apart 5/6 of a unit of time on the time line.

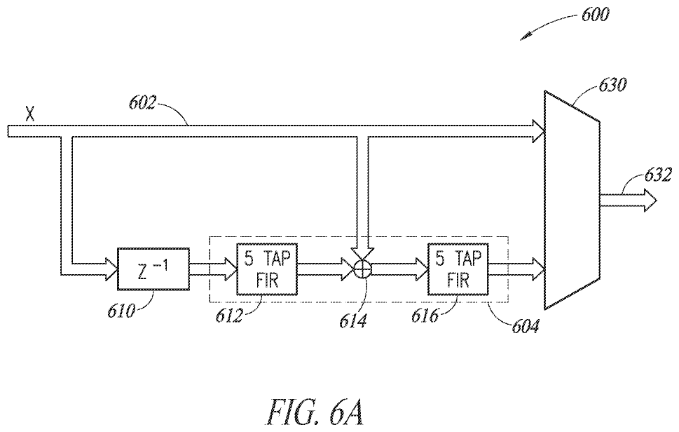

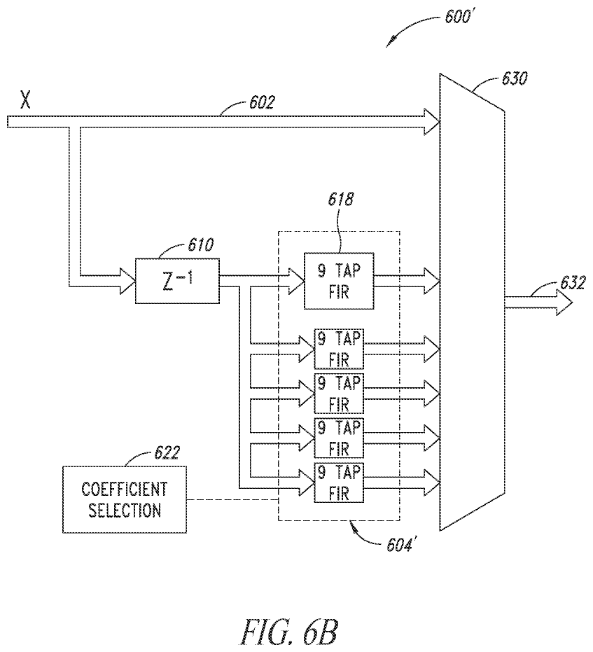

FIGS. 6A and 6B illustrate example implementations of fractional interpolation filters systems 600, 600′, and will be discussed for convenience with reference to the example fractional interpolation of FIG. 5A. One of skill in the art would recognize, after reviewing the present disclosure, that the embodiments of FIGS. 6A and 6B may be employed to implement other fractional interpolations by selecting appropriate filter coefficients, as discussed below.

As shown in FIG. 6A, an interpolation filter system 600 includes one or more interpolation branches 604 which receive a delayed version of the input signal X from an input line 602 through a phase delay element 610. For ease of illustration, only one branch 604 is shown in FIG. 6A. As illustrated, a branch 604 includes vector magnitude scaling circuitry 612 implemented using a 5 tap finite impulse response (FIR) filter, adding circuitry 614, and magnitude compensation scaling circuitry 616 implemented using another 5 tap FIR filter. With reference to FIG. 5, the input line 602 may provide the symbol 530, and respective branches 604 may provide respective ones of the other symbols 532, 534, 536, 538 and 540 of the interpolated output signal, with the multiplexing circuitry 632 selecting the appropriate symbol to provide at a given time (e.g., a 6:1 multiplexing scheme). The inventors have observed that using 5-tap FIR filters to implement the vector magnitude scaling circuitry 612 and the magnitude compensation scaling circuitry provides satisfactory results.

Instead of using a plurality of interpolation branches 604, a single interpolation branch may be employed, together with coefficient selection circuitry (see FIG. 6B) to select coefficients to provide vector magnitude scaling to produce the desired amount of phase shift and coefficients to provide the desired amount of compensation scaling. For example, a first phase-shifted symbol 532 is shifted by β/6 from input symbol 512; a second phase-shifted symbol 534 is shifted by 2β/6 from input symbol 514, a third phase-shifted symbol 536 is shifted by 3β/6 from input symbol 516, a fourth phase-shifted symbol 538 is shifted by 4β/6 from input symbol 518, and a fifth phase-shifted symbol 540 is shifted by 5β/6 from input symbol 520.

The inventors have realized that for fractional interpolation, the interpolation circuitry 604 may be replaced with simplified interpolation circuitry 604′ including, for example, 5 branches, as shown in FIG. 6B. The 5 tap FIR filter implementing the vector magnitude scaling circuitry 612, the adder 614 and the 5 tap FIR filter implementing the magnitude compensation scaling circuitry 616 of a branch have been replaced with a 9 tap FIR filter 618. In an embodiment, filter coefficients for the 9 tap FIR filters 618 may be selected using optional coefficient selection circuitry 622 (as illustrated, to select the 5 phases needed to provide the desired symbols shown in FIG. 5A. For example, a first phase-shifted symbol 532 is shifted by β/6 from input symbol 512; a second phase-shifted symbol 534 is shifted by 2β/6 from input symbol 514, a third phase-shifted symbol 536 is shifted by 3β/6 from input symbol 516, a fourth phase-shifted symbol 538 is shifted by 4β/6 from input symbol 518, and a fifth phase-shifted symbol 540 is shifted by 5β/6 from input symbol 520.

Each phase in this example fractional interpolation case, Phaseᵢ, may be represented as follows:

$${Phase}_{i} = \frac{i β}{6} ∀ i ∈ [ 1 , 5 ] ,$$

where i represents the desired phase-shift to obtain the fractional interpolation.

Based on Phase which is indicative of the desire phase information, 5 different Kᵢ and Bᵢ can be obtained based on the formula described herein.

When interpolating by 6/5, then p=[1,5] and N=6. Kc may be determined according to:

$${K}_{i} = \frac{tan ( \frac{i β}{6} )}{sin β - cos ( β ) tan ( \frac{i β}{6} )}$$

Bᵢ may be determined according to:

$${B}_{i} = \frac{1}{\sqrt{1 + {K}_{i}^{2} + 2 {K}_{i} cos β}} ∀ i ∈ [ 1 , 5 ] ; and$$

$${tan}^{- 1} ( \frac{{K}_{i} sin β}{1 + {K}_{i} cos β} ) = \frac{i β}{6} ∀ i ∈ [ 1 , 5 ] .$$

That is, according to one embodiment of the present disclosure, fractional interpolation of n/m (where n is greater than m) may be obtained. Below provides the summary formula for obtaining the Kᵢ and Bᵢ scaling factors when fractional interpolation by 6/5.

$${K}_{i} = \frac{tan ( \frac{i β}{6} )}{sin β - cos ( β ) tan ( \frac{i β}{6} )} ;$$

$${B}_{i} = \frac{1}{\sqrt{1 + {K}_{í}^{2} + 2 {K}_{i} cos β}} ∀ i ∈ [ 1 , 5 ] .$$

FIG. 5B is an example response diagram based on the magnitude and phase information (Kᵢ and Bᵢ) for phase i=5. Accordingly, the example interpolation architecture may be used for both integer interpolation and fractional interpolation.

FIG. 7 is a functional block diagram of an embodiment of an electronic device or system 700 of the type to which the embodiments, which are described herein, may apply. The system 700 comprises one or more processing cores or circuits 702. The processing cores 702 may comprise, for example, one or more processors, a state machine, a microprocessor, a programmable logic circuit, discrete circuitry, logic gates, registers, etc., and various combinations thereof. The processing cores may control overall operation of the system 700, execution of application programs by the system 700, etc.

The system 700 includes one or more memories 704, such as one or more volatile and/or non-volatile memories which may store, for example, all or part of instructions and data related to control of the system 700, applications and operations performed by the system 700, etc. The system 700 may include one or more sensors 720 (e.g., image sensors, audio sensors, accelerometers, pressure sensors, temperature sensors, encoders, etc.), one or more interfaces 730 (e.g., wireless communication interfaces, wired communication interfaces, bus system interfaces, etc.), one or more controllers 740, such as one or more traction inverters 750, and other circuits 760, which may include antennas, power supplies, etc., and a main bus system 770. The main bus system 770 may include one or more data, address, power and/or control buses coupled to the various components of the system 700.

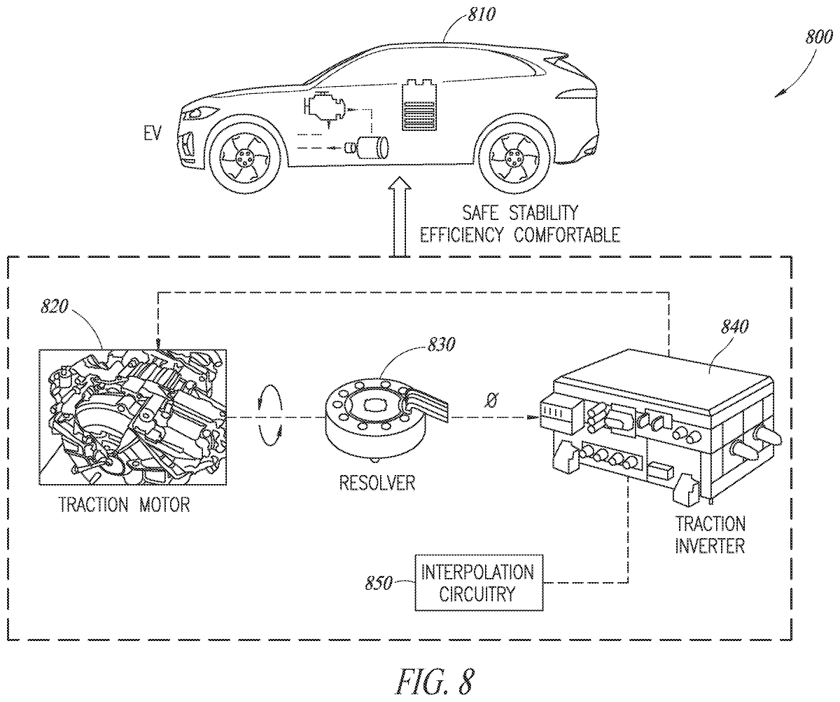

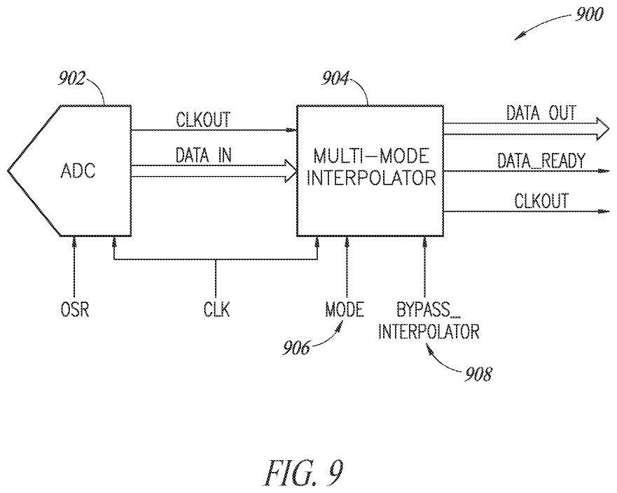

The system 700 also includes one or more interpolators 780, such as one or more of the interpolators 100, 300, 300′, 600, 600′, 850, 904, illustrated in FIG. 1, 3A, 3B, 6A, 6B, 8 or 9, which may generating interpolated output signals using, for example, the method 400 of FIG. 4. The one or more interpolators 700, may, for example, to receive signals, such as sensor signals generated by one or more sensors (e.g., an encoder or resolver of a traction motor), and generated interpolated output signals for use by one or more controllers (e.g., a traction inverter), to generate signals, for example, control signals to control a traction motor (see FIG. 8).

FIG. 8 illustrates an example embodiment of a system 800 that may employ an interpolation architecture according to one or more embodiments of the present disclosure. The system 800 of FIG. 8A includes an electric vehicle 810 having a traction motor 820, a resolver 830, and a traction inverter 840. The system also includes interpolation circuitry 850, such as the interpolation circuitry 100 of FIG. 1, interpolation circuitry 300 of FIG. 3A, interpolation circuitry 300′ of FIG. 3B, interpolation circuitry 780 of FIG. 7, etc. The interpolation circuitry 850 may be used to interpolate signals used by the traction inverter 840 to control the traction motor 820, such as rotation angle sensing signals sensed by the resolver 830.

FIG. 9 illustrates an example embodiment of a system 900 that incorporates an interpolation architecture according to some embodiments of the present disclosure. The system 900 includes an ADC 902 and an interpolator circuit 904. The ADC 902 receives an input signal and provides a digital signal to be interpolated to the interpolator circuit 904, such as the signal X(n) described above with reference to FIG. 1. The interpolator circuit 904 has a mode control input 906 and a bypass control input 908. The mode control input 906 may be used to indicate a number of samples N desired in the interpolated output signal, which may be used by the interpolator circuit 904 to determine a number of branches to employ and the vector magnitude scaling factors Kᵢ and magnitude compensation scaling factors Bᵢ to be employed. For example, a controller (e.g., one of the controllers 740 of FIG. 7), may generate a mode control signal provided to the mode control input of the interpolator circuit 904. The bypass control input 908 may be used to indicate to the interpolator circuit 904 to bypass interpolation and provide the input signal as an output. For example, a controller (e.g., one of the controllers 740 of FIG. 7), may generate a bypass control signal provided to the bypass control input of the interpolator circuit 904.

Embodiments may facilitate providing significant improvements in area and computational costs and delay. For example, a polyphase 63-tap half-band filter conventional fractional interpolator implementation would require 32 registers, along with 32 multiplications and 32 additions and a corresponding delay. A 15 tap FIR filter implementation of an embodiment may provide satisfactory results using 15 registers with 15 multiplications and 15 additions, with significantly less system delay.

In an embodiment, a device comprises: an input, which, in operation, receives an input signal; a phase delay element coupled to the input, wherein the phase delay element, in operation, generates a delayed signal based on the input signal; vector magnitude scaling circuitry coupled to the phase delay element, wherein the vector magnitude scaling circuitry, in operation, applies vector magnitude scaling to the delayed signal, generating one or more vector magnitude scaled signals; adding circuitry coupled to the input and to the vector magnitude scaling circuitry, wherein the adding circuitry, in operation, adds the input signal to the one or more vector magnitude scaled signals, generating one or more phase-shifted signals; magnitude compensation scaling circuitry coupled to the adding circuitry, wherein the magnitude compensation circuitry, in operation, applies compensation scaling to the one or more phase-shifted signals, generating one or more compensated signals; and multiplexing circuitry coupled to the input and to the magnitude compensation circuitry, wherein the multiplexing circuitry, in operation, combines the input signal and the one or more compensated signals, generating an interpolated output signal.

In an embodiment, the device comprises a plurality of interpolation branches, each interpolation branch being coupled between the phase delay element and the multiplexing circuitry and including: a branch of the vector magnitude scaling circuitry, which, in operation, applies a respective vector magnitude scaling operation to the delayed signal, generating a respective one of the one or more vector magnitude scaled signals; a branch of the adding circuitry, coupled to the branch of the vector magnitude scaling circuitry and to the input, wherein the branch of the adding circuitry, in operation, adds the input signal to the respective one of the one or more vector magnitude scaled signals, generating a respective one of the one or more phase-shifted signals; and a branch of the magnitude compensation circuitry, coupled to the branch of the adding circuitry, wherein the branch of the magnitude compensation circuitry applies a respective compensation scaling operation to the respective one of the one or more phase-shifted signals, generating a respective one of the one or more compensated signals. In an embodiment, the respective vector magnitude scaling operation of a branch comprises applying a vector magnitude scaling factor Kᵢ for a branch i of the plurality of interpolation branches. In an embodiment, Kᵢ is determined according to:

$${tan}^{- 1} ( \frac{{K}_{i} sin ( β )}{1 + {K}_{i} cos ( β )} ) = \frac{i β}{N} ,$$

wherein N represents a number of samples, and β represents a digital angular frequency.

In an embodiment, the respective compensation scaling operation of a branch comprises applying a compensation scaling factor Bᵢ for the branch i of the plurality of interpolation branches. In an embodiment, Bᵢ is determined according to:

$${B}_{i} = \frac{1}{\sqrt{1 + {K}_{i}^{2} + 2 {K}_{i} cos ( β )}} .$$

In an embodiment, a compensated signal Yᵢ of the branch corresponds to

Yᵢ=Bᵢ(X(n)+KᵢX(n−1); and

the input signal X(n) corresponds to

$$X = {\sum }_{k < N} sin ( 2 * π * k * \frac{n}{2 N} ) ,$$

wherein n is a time stamp, and k/N is a digital frequency.

In an embodiment, the branch of the vector magnitude scaling circuitry includes a finite impulse response filter. In an embodiment, the branch of the magnitude compensation scaling circuitry includes a finite impulse response filter. In an embodiment, the vector magnitude scaling circuitry includes a finite impulse response filter. In an embodiment, the magnitude compensation scaling circuitry includes a finite impulse response filter, and the interpolation circuitry, in operation, generates a fractional interpolation output signal.

In an embodiment, a method comprises: generating a delayed signal based on an input signal; applying vector magnitude scaling to the delayed signal, generating one or more vector magnitude scaled signals; adding the input signal to the one or more vector magnitude scaled signals, generating one or more phase-shifted signals; applying compensation scaling to the one or more phase-shifted signals, generating one or more compensated signals; and combining the input signal and the one or more compensated signals, generating an interpolated output signal. In an embodiment, the applying vector magnitude scaling comprises applying a plurality of vector magnitude scaling factors to the delayed signal, generating a corresponding plurality of vector magnitude scaled signals; the adding the input signal to the one or more vector magnitude scaled signals comprises adding the input signal to each of the plurality of vector magnitude scaled signals, generating a corresponding plurality of phase-shifted signals; the applying compensation scaling to the one or more phase-shifted signals comprising applying a respective compensation scaling factor to the plurality of phase-shifted signals, generating a plurality of compensated signals; and the combining the input signal and the one or more compensated signals comprises time multiplexing the input signal and the plurality of compensated signals, generating the interpolated output signal. In an embodiment, a vector magnitude scaling factor K of the plurality of vector magnitude scaling factors is determined according to:

$${tan}^{- 1} ( \frac{{K}_{i} sin ( β )}{1 + {K}_{i} cos ( β )} ) = \frac{i β}{N} ,$$

wherein N represents a number of samples, i is an order of the vector magnitude scaling factor in the plurality of vector magnitude scaling factors and β represents a digital angular frequency.

In an embodiment, a compensation scaling factor Bᵢ of the plurality of compensation scaling factors is determined according to:

$${B}_{i} = \frac{1}{\sqrt{1 + {K}_{i}^{2} + 2 {K}_{i} cos ( β )}}$$

In an embodiment, a compensated signal Yᵢ of the plurality of compensated signals corresponds to Yᵢ=Bᵢ(X(n)+KᵢX(n−1); and the input signal X(n) corresponds to

$$X = {\sum }_{k < N} sin ( 2 * π * k * \frac{n}{2 N} ) ,$$

wherein n is a time stamp, and k/N is a digital frequency.

In an embodiment, a system comprises a memory, and interpolation circuitry coupled to the memory and multiplexing circuitry. The interpolation circuitry includes: an input, which, in operation, receives an input signal; a phase delay element coupled to the input, wherein the phase delay element, in operation, generates a delayed signal based on the input signal; vector magnitude scaling circuitry coupled to the phase delay element, wherein the vector magnitude scaling circuitry, in operation, applies vector magnitude scaling to the delayed signal, generating one or more vector magnitude scaled signals; adding circuitry coupled to the input and to the vector magnitude scaling circuitry, wherein the adding circuitry, in operation, adds the input signal to the one or more vector magnitude scaled signals, generating one or more phase-shifted signals; magnitude compensation scaling circuitry coupled to the adding circuitry, wherein the magnitude compensation circuitry applies compensation scaling to the one or more phase-shifted signals, generating one or more compensated signals; and multiplexing circuitry coupled to the input and to the magnitude compensation circuitry. The multiplexing circuitry, in operation, combines the input signal and the one or more compensated signals, generating an interpolated output signal.

In an embodiment, the interpolation circuitry comprises a plurality of interpolation branches, each interpolation branch being coupled between the phase delay element and the multiplexing circuitry and including: a branch of the vector magnitude scaling circuitry, which, in operation, applies a respective vector magnitude scaling operation to the delayed signal, generating a respective one of the one or more vector magnitude scaled signals; a branch of the adding circuitry, coupled to the branch of the vector magnitude scaling circuitry and to the input, wherein the branch of the adding circuitry, in operation, adds the input signal to the respective one of the one or more vector magnitude scaled signals, generating a respective one of the one or more phase-shifted signals; and a branch of the magnitude compensation circuitry, coupled to the branch of the adding circuitry, wherein the branch of the magnitude compensation circuitry applies a respective compensation scaling operation to the respective one of the one or more phase-shifted signals, generating a respective one of the one or more compensated signals. In an embodiment, the interpolation circuitry, in operation, determines a number of the one or more compensated signals to combine with the input signal based on an interpolation mode control signal. In an embodiment, the system comprises: a resolver coupled to the input, wherein the resolver, in operation, senses rotational angles associated with a traction motor, and generates the input signal based on the sensed rotational angles; and a traction inverter coupled to the multiplexing circuitry, wherein the traction inverter, in operation, generates signals to control a traction motor based on the interpolated signal.

In an embodiment, a non-transitory computer readable medium's contents cause interpolation circuitry to perform a method. The method comprises: generating a delayed signal based on an input signal; applying vector magnitude scaling to the delayed signal, generating one or more vector magnitude scaled signals; adding the input signal to the one or more vector magnitude scaled signals, generating one or more phase-shifted signals; applying compensation scaling to the one or more phase-shifted signals, generating one or more compensated signals; and combining the input signal and the one or more compensated signals, generating an interpolated output signal. In an embodiment, the method comprises controlling a traction motor based on the interpolated output signal. In an embodiment, the contents comprise instructions executed by the interpolation circuitry.

In an embodiment, a device comprises: an input, which in operation receives an input signal; a delay element coupled to the input, which, in operation, generates a delayed signal based on the input signal; an adder, coupled to the input and to the delay element, wherein the adder, in operation, adds the delayed signal and the input signal, generating a combined signal; a finite impulse response filter coupled to the adder, wherein the finite impulse response filter, in operation, generates a phase-shifted and scaled signal based on the combined signal; and multiplexing circuitry coupled to the input and the finite impulse response filter, wherein the multiplexing circuitry, in operation, time multiplexes the input signal and the phase-shifted and scaled signal, generating an interpolated output signal.

In an embodiment, a device comprises: an input, which in operation receives an input signal; a delay element coupled to the input, which, in operation, generates a delayed signal based on the input signal; one or more finite impulse response filters coupled to the delay element, wherein the finite impulse response filters, in operation, generate respective phase-shifted and scaled signals based on the delayed signal and respective filter coefficients; and signal combining circuitry coupled to the input and the finite impulse response filter, wherein the signal combining circuitry, in operation, combines the input signal and the phase-shifted and scaled signals, generating a fractional interpolation output signal. In an embodiment, the device comprises: coefficient selection circuitry coupled to the one or more finite impulse response filters, wherein the coefficient selection circuitry, in operation, provides the respective filter coefficients to the finite impulse response filters.

In an embodiment, a device comprises: an input, which, in operation, receives an input signal; a phase delay element coupled to the input, wherein the phase delay element, in operation, generates a delayed signal based on the input signal; phase-shifting circuitry coupled to the input and to the delay element, wherein the phase-shifting circuitry, in operation, generates one or more phase-shifted signals based on the input signal and the delayed signal; magnitude compensation scaling circuitry coupled to the phase-shifting circuitry, wherein the magnitude compensation circuitry, in operation, applies compensation scaling to the one or more phase-shifted signals; and signal combining circuitry coupled to the input and to the magnitude compensation circuitry, wherein the signal combining circuitry, in operation, combines the input signal and the one or more compensated signals, generating an interpolated output signal. In an embodiment, the device comprises: vector magnitude scaling circuitry coupled between the phase delay element and the phase-shifting circuitry, wherein the vector magnitude scaling circuitry, in operation, applies vector magnitude scaling to the delayed signal, generating one or more vector magnitude scaled signals, wherein the phase-shifting circuitry, in operation, adds the input signal to the one or more vector magnitude scaled signals, generating the one or more phase-shifted signals, wherein the magnitude compensation circuitry, in operation, applies compensation scaling to the one or more phase-shifted signals, generating one or more compensated signals. In an embodiment, the device comprises a plurality of interpolation branches, each interpolation branch being coupled between the phase delay element and the multiplexing circuitry and including: a branch of the vector magnitude scaling circuitry, which, in operation, applies a respective vector magnitude scaling operation to the delayed signal, generating a respective one of the one or more vector magnitude scaled signals; a branch of the phase-shifting circuitry, coupled to the branch of the vector magnitude scaling circuitry and to the input, wherein the branch of the phase-shifting circuitry, in operation, adds the input signal to the respective one of the one or more vector magnitude scaled signals, generating a respective one of the one or more phase-shifted signals; and a branch of the magnitude compensation circuitry, coupled to the branch of the adding circuitry, wherein the branch of the magnitude compensation circuitry applies a respective compensation scaling operation to the respective one of the one or more phase-shifted signals, generating a respective one of the one or more compensated signals.

In an embodiment, a device comprises: an input, which, in operation, receives an input signal; interpolation circuitry, coupled to the input, wherein the interpolation circuitry, in operation: generates a delayed signal based on the input signal; generates one or more phase-shifted signals based on the delayed signal and the input signal; applies magnitude compensation scaling to the one or more phase-shifted signals, generating corresponding magnitude compensated signals; and combines the input signal with the one or more magnitude compensated signals, generating an interpolated signal. In an embodiment, the interpolation circuitry, in operation, generates the one or more phase-shifted signals by: applying magnitude scaling to the delayed signal, generating one or more magnitude scaled signals; and adding the input signal to the one or more magnitude scaled signals, generating the one or more phase-shifted signals.

Some embodiments may take the form of or comprise computer program products. For example, according to one embodiment there is provided a computer readable medium comprising a computer program adapted to perform one or more of the methods or functions described above. The medium may be a physical storage medium, such as for example a Read Only Memory (ROM) chip, or a disk such as a Digital Versatile Disk (DVD-ROM), Compact Disk (CD-ROM), a hard disk, a memory, a network, or a portable media article to be read by an appropriate drive or via an appropriate connection, including as encoded in one or more barcodes or other related codes stored on one or more such computer-readable mediums and being readable by an appropriate reader device.

Furthermore, in some embodiments, some or all of the methods and/or functionality may be implemented or provided in other manners, such as at least partially in firmware and/or hardware, including, but not limited to, one or more application-specific integrated circuits (ASICs), digital signal processors, discrete circuitry, logic gates, standard integrated circuits, controllers (e.g., by executing appropriate instructions, and including microcontrollers and/or embedded controllers), field-programmable gate arrays (FPGAs), complex programmable logic devices (CPLDs), etc., as well as devices that employ RFID technology, and various combinations thereof.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
an input, which, in operation, receives an input signal;
a phase delay element coupled to the input, wherein the phase delay element, in operation, generates a delayed signal based on the input signal;
vector magnitude scaling circuitry coupled to the phase delay element, wherein the vector magnitude scaling circuitry, in operation, applies vector magnitude scaling to the delayed signal, generating one or more vector magnitude scaled signals;
adding circuitry coupled to the input and to the vector magnitude scaling circuitry, wherein the adding circuitry, in operation, adds the input signal to the one or more vector magnitude scaled signals, generating one or more phase-shifted signals;
magnitude compensation scaling circuitry coupled to the adding circuitry, wherein the magnitude compensation circuitry, in operation, applies compensation scaling to the one or more phase-shifted signals, generating one or more compensated signals; and
multiplexing circuitry coupled to the input and to the magnitude compensation circuitry, wherein the multiplexing circuitry, in operation, combines the input signal and the one or more compensated signals, generating an interpolated output signal.

2. The device of claim 1, comprising a plurality of interpolation branches, each interpolation branch being coupled between the phase delay element and the multiplexing circuitry and including:
a branch of the vector magnitude scaling circuitry, which, in operation, applies a respective vector magnitude scaling operation to the delayed signal, generating a respective one of the one or more vector magnitude scaled signals;
a branch of the adding circuitry, coupled to the branch of the vector magnitude scaling circuitry and to the input, wherein the branch of the adding circuitry, in operation, adds the input signal to the respective one of the one or more vector magnitude scaled signals, generating a respective one of the one or more phase-shifted signals; and
a branch of the magnitude compensation circuitry, coupled to the branch of the adding circuitry, wherein the branch of the magnitude compensation circuitry applies a respective compensation scaling operation to the respective one of the one or more phase-shifted signals, generating a respective one of the one or more compensated signals.

3. The device of claim 2, wherein the respective vector magnitude scaling operation of a branch comprises applying a vector magnitude scaling factor Kᵢ for a branch i of the plurality of interpolation branches.

4. The device of claim 3, wherein Kᵢ is determined according to:
$${tan}^{- 1} ( \frac{{K}_{i} sin ( β )}{1 + {K}_{i} cos ( β )} ) = \frac{i β}{N} ,$$
wherein N represents a number of samples, and β represents a digital angular frequency.

5. The device of claim 4 wherein the respective compensation scaling operation of a branch comprises applying a compensation scaling factor Bᵢ for the branch i of the plurality of interpolation branches.

6. The device of claim 5, wherein Bᵢ is determined according to:
$${B}_{i} = \frac{1}{\sqrt{1 + {K}_{i}^{2} + 2 {K}_{i} cos ( β )}} .$$

7. The device of claim 4, wherein,
a compensated signal Yᵢ of the branch corresponds to
Yᵢ=Bᵢ(X(n)+KᵢX(n−1); and
the input signal X(n) corresponds to
$$X = {\sum }_{k < N} sin ( 2 * π * k * \frac{n}{2 N} ) ,$$
wherein n is a time stamp, and
k/N is a digital frequency.

8. The device of claim 2, wherein the branch of the vector magnitude scaling circuitry includes a finite impulse response filter.

9. The device of claim 8, wherein the branch of the magnitude compensation scaling circuitry includes a finite impulse response filter.

10. The device of claim 1, wherein the vector magnitude scaling circuitry includes a finite impulse response filter.

11. The device of claim 10, wherein the magnitude compensation scaling circuitry includes a finite impulse response filter, and the interpolation circuitry, in operation, generates a fractional interpolation output signal.

12.-23. (canceled)

24. A device, comprising:
an input, which in operation receives an input signal;
a delay element coupled to the input, which, in operation, generates a delayed signal based on the input signal;
an adder, coupled to the input and to the delay element, wherein the adder, in operation, adds the delayed signal and the input signal, generating a combined signal;
a finite impulse response filter coupled to the adder, wherein the finite impulse response filter, in operation, generates a phase-shifted and scaled signal based on the combined signal; and
multiplexing circuitry coupled to the input and the finite impulse response filter, wherein the multiplexing circuitry, in operation, time multiplexes the input signal and the phase-shifted and scaled signal, generating an interpolated output signal.

25. A device, comprising:
an input, which in operation receives an input signal;
a delay element coupled to the input, which, in operation, generates a delayed signal based on the input signal;
one or more finite impulse response filters coupled to the delay element, wherein the finite impulse response filters, in operation, generate respective phase-shifted and scaled signals based on the delayed signal and respective filter coefficients; and
signal combining circuitry coupled to the input and the finite impulse response filter, wherein the signal combining circuitry, in operation, combines the input signal and the phase-shifted and scaled signals, generating a fractional interpolation output signal.

26. The device of claim 25, comprising:
coefficient selection circuitry coupled to the one or more finite impulse response filters, wherein the coefficient selection circuitry, in operation, provides the respective filter coefficients to the finite impulse response filters.

27. A device, comprising:
an input, which, in operation, receives an input signal;
a phase delay element coupled to the input, wherein the phase delay element, in operation, generates a delayed signal based on the input signal;
phase-shifting circuitry coupled to the input and to the delay element, wherein the phase-shifting circuitry, in operation, generates one or more phase-shifted signals based on the input signal and the delayed signal;
magnitude compensation scaling circuitry coupled to the phase-shifting circuitry, wherein the magnitude compensation circuitry, in operation, applies compensation scaling to the one or more phase-shifted signals; and
signal combining circuitry coupled to the input and to the magnitude compensation circuitry, wherein the signal combining circuitry, in operation, combines the input signal and the one or more compensated signals, generating an interpolated output signal.

28. The device according to claim 27, comprising:
vector magnitude scaling circuitry coupled between the phase delay element and the phase-shifting circuitry, wherein the vector magnitude scaling circuitry, in operation, applies vector magnitude scaling to the delayed signal, generating one or more vector magnitude scaled signals,
wherein the phase-shifting circuitry, in operation, adds the input signal to the one or more vector magnitude scaled signals, generating the one or more phase-shifted signals,
wherein the magnitude compensation circuitry, in operation, applies compensation scaling to the one or more phase-shifted signals, generating one or more compensated signals.

29. The device of claim 28, comprising a plurality of interpolation branches, each interpolation branch being coupled between the phase delay element and the multiplexing circuitry and including:
a branch of the vector magnitude scaling circuitry, which, in operation, applies a respective vector magnitude scaling operation to the delayed signal, generating a respective one of the one or more vector magnitude scaled signals;
a branch of the phase-shifting circuitry, coupled to the branch of the vector magnitude scaling circuitry and to the input, wherein the branch of the phase-shifting circuitry, in operation, adds the input signal to the respective one of the one or more vector magnitude scaled signals, generating a respective one of the one or more phase-shifted signals; and
a branch of the magnitude compensation circuitry, coupled to the branch of the adding circuitry, wherein the branch of the magnitude compensation circuitry applies a respective compensation scaling operation to the respective one of the one or more phase-shifted signals, generating a respective one of the one or more compensated signals.

30. A device, comprising:
an input, which, in operation, receives an input signal;
interpolation circuitry, coupled to the input, wherein the interpolation circuitry, in operation:
generates a delayed signal based on the input signal;
generates one or more phase-shifted signals based on the delayed signal and the input signal;
applies magnitude compensation scaling to the one or more phase-shifted signals, generating corresponding magnitude compensated signals; and
combines the input signal with the one or more magnitude compensated signals, generating an interpolated signal.

31. The device of claim 30, wherein the interpolation circuitry, in operation, generates the one or more phase-shifted signals by:
applying magnitude scaling to the delayed signal, generating one or more magnitude scaled signals; and
adds the input signal to the one or more magnitude scaled signals, generating the one or more phase-shifted signals.
